(19) United States
(12) Patent Application Publication
(10) Pub. No.: US 2026/0226347 A1
(43) Pub. Date: Aug. 6, 2026

(54) NANOCRYSTALS AND METHODS OF MAKING

(71) Applicant: Alliance for Energy Innovation, LLC, Golden, CO (US)

(72) Inventors: Matthew Peter HAUTZINGER, Golden, CO (US); Sage Russell BAUERS, Lakewood, CO (US); Shaham QUADIR, Lakewood, CO (US)

(21) Appl. No.: 19/464,920

(22) Filed: Jan. 30, 2026

Related U.S. Application Data
(60) Provisional application No. 63/753,125, filed on Feb. 3, 2025.

(51) Int. Cl. C09K 11/71; C09K 11/06; C09K 113/00; H10F 77/12; H10F 77/14; H10H 20/812; H10H 20/818; H10H 20/822; H10K 50/115; H10K 85/00

(52) U.S. Cl. CPC C09K 11/71; C09K 11/06; H10F 77/12; H10F 77/1433; H10F 77/1437; H10H 20/812; H10H 20/818; H10H 20/822; H10K 50/115; H10K 85/00; C09K 2113/00; C09K 2211/1025

(57) ABSTRACT

The present disclosure relates to a composition that includes a nanocrystal characterized by a Zintl-phase, a P-3m1 space group, a diameter between 2 nm and 25 nm, and a bandgap between 0.6 eV and 2.2 eV.

### CROSS-REFERENCE TO RELATED APPLICATIONS

This application claims the benefit of U.S. Provisional Application No. 63/753,125 filed Feb. 3, 2025, the contents of which are incorporated herein by reference in their entirety.

### CONTRACTUAL ORIGIN

This invention was made with government support under Contract No. DE-AC36-08GO28308 awarded by the Department of Energy. The government has certain rights in the invention.

### BACKGROUND

Zintl-phase nanocrystals are semiconducting materials having a number of desirable characteristics including high tolerance to electronic defects, low enthalpy of formation and a band gap that is well suited for common optoelectronic applications like lighting, bioimaging, lasing, communication, and solar energy harvesting. Unfortunately, the currently available methods for preparing Zintl-phase materials are either completely intractable or require significant growth engineering to be incorporated into devices. Thus, there remains a need for improved methods for synthesizing Zintl-phase nanocrystals with enhanced functionality that are reliable, scalable, and economically viable.

### SUMMARY

An aspect of the present disclosure is a composition that includes a nanocrystal characterized by a Zintl-phase, a P-3m1 space group, a diameter between 2 nm and 25 nm, and a bandgap between 0.6 eV and 2.2 eV. In some embodiments of the present disclosure, the nanocrystal may have a stoichiometry as defined by AM₂X₂, where M includes at least one of a p-block element, a transition metal, or a combination thereof, X includes a highly electronegative element, and A includes at least one of an alkali element, an alkaline earth element, or a combination thereof. In some embodiments of the present disclosure, M may include at least one of cadmium, zinc, mercury, or a combination thereof. In some embodiments of the present disclosure, X may include at least one silicon, nitrogen, phosphorus, arsenic, antimony, bismuth, or a combination thereof. In some embodiments of the present disclosure, A may include at least one of barium, calcium, beryllium, strontium, magnesium, or a combination thereof. In some embodiments of the present disclosure, the nanocrystal may have a stoichiometry that includes at least one of BaCd₂P₂, CaZn₂P₂, SrCd₂P₂, BaCd₂As₂, CaZn₂As₂, SrCd₂As₂, or a combination thereof.

In some embodiments of the present disclosure, the composition may further a ligand, where the ligand may be ionically bonded to the nanocrystal. In some embodiments of the present disclosure, the ligand may include an organic ligand, an inorganic ligand, or a combination thereof. In some embodiments of the present disclosure, the organic ligand may include at least one of oleic acid, sodium oleate, oleylamine, trioctylphosphine, and trioctylphosphine oxide, or a combination thereof. In some embodiments of the present disclosure, the inorganic ligand may be a halide.

In some embodiments of the present disclosure, the bandgap may be between 1.4 eV and 1.9 eV. In some embodiments of the present disclosure, the diameter may be between 3 nm to 9 nm. In some embodiments of the present disclosure, the composition may be characterized by a recombination lifetime of greater than 100 ns to 1000 ns. In some embodiments of the present disclosure, the nanocrystal may have a morphology comprising at least one of a quantum dot, a nanowire, a nanoplate, an amorphous morphology, or a combination thereof. In some embodiments of the present disclosure, the composition may be characterized by being stable when immersed in liquid water at 25° C.

An aspect of the present disclosure is a device that includes a layer of a nanocrystal, where the nanocrystal includes a Zintl-phase, a P-3m1 space group, a diameter between 2 nm and 25 nm, and a bandgap between 0.6 eV and 2.2 eV. Further, the layer may have a thickness between 3 nm and 3 μm or between 3 nm and 1000 nm or between 3 nm and 500. In some embodiments of the present disclosure, the device may further include a first charge transport layer (first CTL) and a second CTL, where the layer of the nanocrystal is positioned between the first CTL and the second CTL.

In some embodiments of the present disclosure, is a method that includes dissolving a first precursor and a second precursor in a first solution, adding a third precursor to the first solution to form a second solution, and mixing the second solution, where during the mixing, the nanocrystals are formed, the nanocrystals are characterized by a Zintl-phase having a composition as defined by AM₂X₂, where the first precursor comprises A, the second precursor comprises M, and the third precursor comprises X. In some embodiments of the present disclosure, prior to the adding step, the method may include removing water from the first solution. In some embodiments of the present disclosure, prior to the adding step, the first solution may be heated to a temperature between 20° C. to 300° C. or between 110° C. to 220° C.

### BRIEF DESCRIPTION OF DRAWINGS

Some embodiments are illustrated in referenced figures of the drawings. It is intended that the embodiments and figures disclosed herein are to be considered illustrative rather than limiting.

FIG. 1 illustrates a nanocrystal with ligands, according to some embodiments of the present disclosure.

FIG. 2 illustrates a device including a layer of nanocrystals, according to some embodiments of the present disclosure.

FIG. 3 illustrates a method for making nanocrystals, according to some embodiments of the present disclosure.

FIG. 4 illustrates absorbance and photoluminescence spectra (PL) (λₑₓ=405 nm; 3.06 eV) of BaCd₂P₂ QDs synthesized at various injection temperatures as listed on the plot, according to some embodiments of the present disclosure. The PL emission was tuned from 1.47 eV to 1.80 eV. The feature at 1.3 eV is due to a detector change.

FIG. 5 illustrates absorbance and PL spectra for BaCd₂P₂ QDs grown at 220° C. with the PL maxima and absorption onset at 850 nm in agreement with bulk BaCd₂P₂ and the 190° C. growth, according to some embodiments of the present disclosure. The feature at ~950 nm is due to a detector change.

FIG. 6A illustrates images and phase characterization of BaCd₂P₂ QDs, according to some embodiments of the present disclosure. Panel (a) High-Angle Annular Dark-Field Scanning Transmission Electron Microscopy (HAADF-STEM) of the synthesized BaCd₂P₂ QDs. Panel (b) TEM images of larger BaCd₂P₂ QDs highlighting lattice fringes. Panel (c) Selected area electron diffraction, which can be indexed to the P-3m1 bulk phase. Values shown in Table 1.

FIG. 6B illustrates XRD of BaCd₂P₂ QDs with calculated bulk PXRD pattern for BaCd₂P₂ (space group P-3m1), according to some embodiments of the present disclosure.

FIG. 6C illustrates Raman spectra of QDs showing two discrete features in both bulk and the QDs, according to some embodiments of the present disclosure.

FIG. 7 illustrates electron microscopy images of BaCd₂P₂ QDs, according to some embodiments of the present disclosure. Panels (a-c) TEM of particles grown at 190° C. There is a wide range of shapes, possibly due to Ostwald ripening, but the particles are as long as 11 nm and as short as 7 nm (~9 nm). Panel (c) shows lattice distance of 0.23 nm in correspondence with the (110) plane. Panels (d-f) STEM HADDF images of particles grown at 160° C. with particles 5 nm in size. Panel f shows some areas of periodicity. The particles crystallinity may be obscured due to washing procedures leading to excess Ba-ligand and Cd-ligand species present. Panels (g-h) TEM of particles grown at 110° C. with particles sized at 3 nm. Panel (i) Illustrates the packing of QDs into a superlattice-like structure.

FIG. 8 illustrates a plot of time-resolved photoluminescence (TRPL) of BaCd₂P₂ QDs (λex=500 nm; 2.48 eV), according to some embodiments of the present disclosure. Plot of the PL decay with a biexponential fit (solid lines) produced decay lifetimes of 61 ns (25%) and 200 ns (75%) (power=7.0 μW) (data set marked with (*)) and 70 ns (33%) and 210 ns (67%) (power=0.16 μW) (data set marked with (\hat{ })). T0=83 ns. GIRF=10.5 ns.

FIG. 9A illustrates a TEM image of quantum dots self-assembled into a structure resembling a superlattice with a 4-5 nm spacing between higher contrast inorganic layers (the QDs), according to some embodiments of the present disclosure. Inset illustrates a zoomed in image (scale bar 20 nm).

FIG. 9B illustrates XRD spectra on a superlattice with a fit of 4.5 nm spacing in excellent agreement with the TEM images, according to some embodiments of the present disclosure. Inset illustrates a linear fit to peak index vs. positions such that the slope is d.

FIG. 10A illustrates Cd/Zn cation exchanged Ba(CdₓZn₁₋ₓ)₂P₂ QDs, according to some embodiments of the present disclosure. The curves/sample for 170° C. growth is the same as FIG. 4 and is the starting position of the absorbance/PL. The PL of the ZnI₂-treated BaCd₂P₂ QDs is at 1.88 eV indicating partial Zn exchange to form Ba(CdₓZn₁₋ₓ)₂P₂.

FIG. 10B illustrates in Panel (a) and in Panel (b) selected area electron diffraction patterns, according to some embodiments of the present disclosure.

FIG. 10C illustrates energy dispersive x-ray spectroscopy of the exchanged QDs showing Zn incorporation (EDX), according to some embodiments of the present disclosure.

FIG. 11A illustrates stoichiometry and ligand impact on QD growth with a comparison of TOPO vs. OLAM on the absorbance/PL in a 160° C. growth temperature, according to some embodiments of the present disclosure. For samples with similar concentrations, the TOPO growth produced much larger PL counts than OLAM.

FIG. 11B illustrates the effects of (TMSi₃)P lean conditions on absorbance/PL, according to some embodiments of the present disclosure. Labeled on the plot is the ratio of (TMSi₃)P:Cd used during the growth.

FIG. 12 illustrates crystal structures of Zintl-phase compounds Panel (a) Pm-3m structure of BaCd₂P₂; Panel (b) I4/mmm BaZn₂P₂; and Panel (c) a colloidal suspension of BaCd₂P₂ shown under ultraviolet (UV) illumination, according to some embodiments of the present disclosure.

FIG. 13 illustrates XRD spectra of nanocrystal samples compared versus standard calculated patterns of Panel (a) BaZn₂P₂ in the I4/mmm phase and Panel (b) BaCd₂P₂ Pm-3m phase, according to some embodiments of the present disclosure. Yellow highlights indicate peaks that match the I4/mmm phase for this growth (albeit shifted due to new cation composition).

FIG. 14A illustrates thin film layers of BaCd₂P₂, according to some embodiments of the present disclosure. Panels (a, b, c, and d) illustrate SEM images of the BaCd₂P₂ QD nanocrystal layers surface with specks of dust in the corners to show focus. Inset of Panel (a) illustrates optical image of the layer. Panels (e) and (f) show a cross section of BaCd₂P₂ QD nanocrystal layers.

FIG. 14B illustrates TRMC photoconductivity transients of the BaCd₂P₂ QD layer with absorbed photon flux ranging from 2×10¹⁴ to 2×10¹⁵ cm⁻², along with biexponential fits (black curves) of the data, according to some embodiments of the present disclosure.

FIG. 14C illustrates FTIR spectra of a BaCd₂P₂ QD layer, according to some embodiments of the present disclosure.

FIG. 15A illustrates photovoltaic development data, according to some embodiments of the present disclosure. Panel (a) High quality (left) BaCd₂P₂ QD thin film versus poor quality (right) thin film with low build-up. Panel (b) SEM image of BaCd₂P₂ QD thin film in a complete device stack showing a smooth thin film. Squares around the edges are metal pads for electronic contact.

FIG. 15B illustrates an I-V curve showing diode like response and photodiode behavior for the device illustrated in the inset, according to some embodiments of the present disclosure.

FIG. 15C illustrates the same plot as illustrated in FIG. 15B zoomed in to focus on J_{sc} and V_{oc}.

To facilitate understanding, identical reference numerals have been used, where possible, to designate identical elements that are common to the figures. It is contemplated that elements and features of one embodiment may be beneficially incorporated in other embodiments without further recitation.

### REFERENCE NUMBERS

100 . . . composition
110 . . . nanocrystal
120 . . . ligand
200 . . . device
210 . . . layer (of nanocrystals)
220 . . . first charge transport layer (CTL)
230 . . . second CTL
240 . . . first contact
250 . . . second contact
300 . . . method
302 . . . first precursor
304 . . . second precursor
310 . . . dissolving
315 . . . first solution
317 . . . third precursor
320 . . . adding
325 . . . second solution
330 . . . mixing

### DETAILED DESCRIPTION

Among other things, the present disclosure describes the synthesis of AM₂P₂ Zintl-phase colloidal nanocrystals. In some embodiments of the present disclosure, a hot-injection (between 100° C. and 220° C.) of tris(trimethylsilyl)phosphine [(TMSi)₃P] phosphorus precursor into a solution of A and M salts solubilized by oleic acid ligands in a high boiling point solvent. The growth rapidly proceeds to produce colloidally stable AM₂P₂ nanocrystals with bright photoluminescence (PL) at room temperature without further surface modifications (i.e. no shell). The absorption onset and PL emission are tunable based on the growth temperature as different sized nanocrystals are synthesized, in some embodiments in a range between 3 nm and 9 nm. Furthermore, the choice of M species, for example zinc versus cadmium, allows further turning of the optical features. These colloidal nanocrystals, which are distinct from bulk materials, can be solution-processed into numerous optoelectronic applications including solar energy harvesting technologies, light emission technologies, among others.

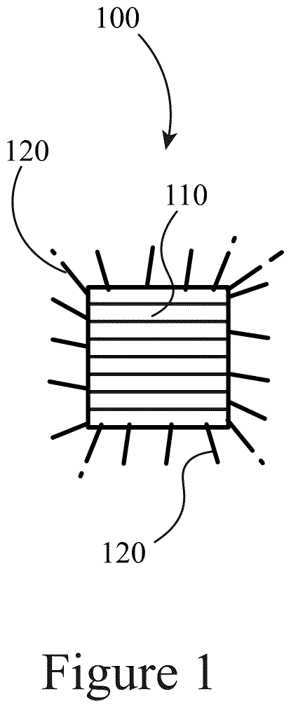

FIG. 1 illustrates a composition 100 that includes a nanocrystal 110 and a ligand 120, according to some embodiments of the present disclosure. As shown herein, a nanocrystal 110 may be characterized by a Zintl-phase having P-3m1 space group, characterized by a diameter between 2 nm and 25 nm and a bandgap between 0.6 eV and 2.2 eV. In some embodiments of the present disclosure, a nanocrystal 110 may have a composition as defined by AM₂X₂, where M includes at least one of a p-block element, a transition metal, or a combination thereof, X includes a highly electronegative element, and A includes at least one of an alkali element, an alkaline earth element, or a combination thereof.

In some embodiments of the present disclosure, M may include at least one of cadmium, zinc, mercury, or a combination thereof. In some embodiments of the present disclosure, X may include at least one nitrogen, phosphorus, arsenic, antimony, bismuth, or a combination thereof. In some embodiments of the present disclosure, A may include at least one of barium, calcium, beryllium, strontium, magnesium, or a combination thereof. In some embodiments of the present disclosure, a Zintl-phase nanocrystal may have a composition that includes at least one of BaCd₂P₂, CaZn₂P₂, SrCd₂P₂, ACd₂As₂, AZn₂As₂, or a combination thereof. In some embodiments of the present disclosure, a nanocrystal 110 may have a composition that includes at least one of BaCd₂P₂, CaZn₂P₂, Ba(CdₓZn₁₋ₓ)₂P₂, or a combination thereof.

In some embodiments of the present disclosure, a nanocrystal 110 may be characterized by a space group selected from the group consisting of at least one of P-3m1, Pnma, I4/mmm, I4/mcm, C2/m, P21/c, P21/m, I4/mmm, and R3m. In some embodiments of the present disclosure, a Zintl-phase nanocrystal may be characterized by a space group that is P-3m1 or I4/mmm.

Referring again to FIG. 1, in some embodiments of the present disclosure, a composition 100 may further include a ligand 120 where the ligand 120 is electrostatically bonded to the nanocrystal 110. In some embodiments of the present disclosure, a ligand 120 may include at least one of an organic ligand, an inorganic ligand, or a combination thereof. In some embodiments of the present disclosure, an organic ligand may include at least one of oleic acid, trioctylphosphine oxide, a halide, a carboxylate, an organo-amine, an organo-phosphine, or a combination thereof. In some embodiments of the present disclosure, an organic ligand may include at least one of oleate, trioctylphosphine oxide, iodide, or a combination thereof. Examples of inorganic ligands include at least one of oleic acid, sodium oleate, oleylamine, trioctylphosphine, and trioctylphosphine oxide. In some embodiments of the present disclosure, an inorganic ligand may include at least one of chloride, bromide, or iodide. In some embodiments of the present disclosure, a nanocrystal may be absent of a ligand 120 (i.e., ligand-free).

In some embodiments of the present disclosure, the semiconducting property of a nanocrystal may include a bandgap between 0.6 eV and 2.2 eV or between 1.4 eV and 1.9 eV. In some embodiments of the present disclosure, a nanocrystal may have a diameter between 2 nm and 25 nm or between 3 nm to 9 nm. In some embodiments of the present disclosure, a nanocrystal may be further characterized by a recombination lifetime of greater than 100 ns up to 1000 ns. In some embodiments of the present disclosure, a nanocrystal may demonstrate the ability to exchange a first element for a second element by cation exchange, for example, exchanging cadmium for zinc. In some embodiments of the present disclosure, a nanocrystal may be characterized by a morphology (i.e., form or shape) that includes at least one of a quantum dot, a nanowire, a nanoplate, or a combination thereof. In some embodiments of the present disclosure, a nanocrystal may be characterized by chemical and mechanical stability when immersed in liquid water, that is, the nanocrystal remains intact as indicated by the observation of photoluminescence when in an aqueous environment at room temperature.

Referring again to FIG. 1, the nanocrystal 110 is illustrated as having a square cross-sectional shape. This is for illustrative purposes and is not intended to be limiting. In some embodiments of the present disclosure, a nanocrystal 110 may have other two-dimensional and three-dimensional shapes. For example, a nanocrystal 110 may have a spherical, elliptical, tubular, and/or other common shapes, including irregular and amorphous shapes.

In some embodiments of the present disclosure, a composition 100 may be dry nanocrystals 110, where the solvent has been removed. Such dry compositions may be nanocrystals 110 with or without ligands 120. Further, in some embodiments of the present disclosure, a composition 100 may be in the form of a colloidal solution, where the nanocrystals 110 are suspended in a solvent, e.g. toluene, hexane, octane. The nanocrystals 110 may be suspended in solution with or without ligands 120.

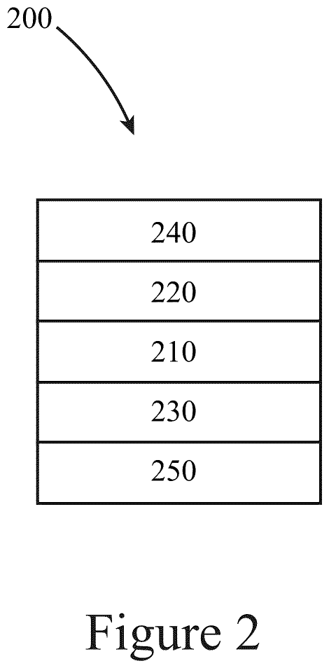

FIG. 2 illustrates a device 200 that includes a layer 210 constructed of nanocrystals 110 like those described above, according to some embodiments of the present disclosure. Thus, a layer 210 may include nanocrystals 110 that are characterized by a Zintl-phase, a P-3m1 space group, a diameter between 2 nm and 25 nm, and a bandgap between 0.6 eV and 2.2 eV. Further, a layer 210 constructed of nanocrystals 110 may have a thickness between 3 nm (that is, a monolayer) and several microns thick. In some embodiments of the present disclosure, the nanocrystals 110 making up a layer 210 may contain ligands 120 ionically bonded to surfaces of the nanocrystals, with the ligands 120 including at organic ligands and/or inorganic ligands. In some embodiments of the present disclosure, the nanocrystals 110 making up a layer 210 may be ligand-free.

In some embodiments of the present disclosure, a layer 210 of nanocrystals may include a composition where there are native colloids having a ligand such as at least one of oleate, trioctylphosphine oxide, a halide, a carboxylate, an organo-amine, an organo-phosphine, or a combination thereof. Further, a layer 210 of nanocrystals may be synthesized using a solid-state ligand exchange that replaces organic ligands with other materials including cadmium acetate (Ac), zinc acetate, CdX₂ (X=Cl, Br, I), and ZnX₂ (X=Cl, Br, I), SbX₃ (X=Cl, Br, I), and PbX₂ (X=Cl, Br, I). In particular, Cd(Ac)₂, Zn(Ac)₂, ZnBr₂, ZnI₂, SbBr₃, SbI₃ and PbI₂ all showed good nanocrystal layer formation, and ZnBr₂SbBr₃ were the best electronically. Salts were solubilized in methylacetate, acetone, or N,N-dimethylformamide. The solid-state ligand exchange was achieved by dipping layers of BaCd₂P₂ with native ligands into a solution containing these materials. The native ligands were either oleic acid with TOPO or oleic acid and oleylamine. They were replaced by the cation (metal species), the anion (halide species or acetate), or some combination thereof.

Referring again to FIG. 2, a device 200 may include a variety of additional layers to yield a device that is fully functional for its intended use, e.g., a photovoltaic device, a display, a sensor, etc. Examples of additional layers include charge transport layers (CTLs) and contacts. The exemplary device 200 illustrated in FIG. 2 includes a first CTL 220 and a second CTL 230, where the layer of nanocrystals 210 is positioned between the first CTL 220 and the second CTL 230. Further, a device 200 may include a first contact 240 and a second contact 250. In some embodiments of the present disclosure, a first CTL 220 may be positioned between a first contact 240 and a layer 210 of nanocrystals. In some embodiments of the present disclosure, a second CTL 230 may be positioned between a second contact 250 and a layer 210 of nanocrystals.

In some embodiments of the present disclosure, a first CTL 220 may be constructed of a hole-transport material. Examples of materials that may be used in a hole-transport layer include Spiro-OMeTAD (2,2′,7,7′-tetrakis(N,N-di-p-methoxyphenylamine)-9,9′-spirobifluorene) and its derivatives; Poly(triarylamine) (PTAA); Poly(3-hexylthiophene) (P3HT); N,N-bis(3-methylphenyl)-N,N-diphenylbenzidine; PEDOT:PSS (Poly(3,4-ethylene dioxythiophene) polystyrene sulfonate polymer); various oxides such as nickel oxide (NiO), copper oxide, vanadium oxide, tin oxide, aluminum oxide, zinc telluride, cobalt zinc oxide, tungsten oxide, and molybdenum oxide (MoOx), which can function as a hole extraction interlayer; sulfides like copper indium sulfide and copper thiocyanate (CuSCN); iodides including copper iodide (CuI) and copper chromium iodide; structured carbon materials such as graphene oxide and carbon nanotubes, including semiconducting single-walled carbon nanotubes (S-SWCNT); other organic small molecules like pyrene, thiophene, porphyrin, and carbazole derivatives (e.g., 1-(N,N-di-p-methoxyphenylamine) pyrene, 2,5-bis(4,4′-bis(methoxyphenyl)aminophen-4″-yl)-3,4-ethylene dioxythiophene, 5,10,15,20-tetrakis(4-bromophenyl) porphyrin, 1,3,6,8-tetra(N,N-p-dimethoxyphenylamino)-9-ethylcarbazole); Spiro-TTB (2,2′,7,7′-Tetra(N,N-di-p-tolyl)amino-9,9-spirobifluorene); polymers such as polyvinylfluoride (PVDF), polyethylene terephthalate (PET), polyimide, poly(ethyleneimine) ethoxylated (PEIE), and siloxanes like Polydimethylsiloxane (PDMS); as well as general classifications including an organic-inorganic perovskite hole transport layer, a metal chalcogenide, a Group III-V material, and a broader category of an oligomer, an elastomer, a polymer, and/or a resin.

In some embodiments of the present disclosure, a second CTL 230 may be constructed of an electron-transport material. Examples of materials that may be used in electron transport layers include metal oxides, carbon-based materials, polymers, specific fullerene derivatives, and other inorganic or organic molecules. Examples of metal oxides and doped metal oxides include titanium dioxide (TiO₂), tin oxide (SnOx or SnO₂), which is also referred to as tin (IV) oxide, zinc oxide (ZnO), niobium pentoxide (Nb₂O₅), tungsten oxide (WO₃), and vanadium oxide (VOₓ). Other specific metal oxides include barium strontium oxide (BaSnO₃), gallium oxide (Ga₂O₃), indium zinc oxide (InZnO), aluminum oxide (Al₂O₃), zirconium dioxide (ZrO₂), indium tin oxide (InSnO), indium oxide (InOx or In₂O₃), iron oxide (Fe₂O₃), molybdenum oxide (MoO₃), and strontium titanate (SrTiO₃). Carbonaceous materials include graphene, fullerenes (e.g. Buckminster fullerene, C60), graphene, and carbon nanotubes. Fullerenes derivatives include phenyl-C61-butyric acid methyl ester. Some polymers may also behave as electron transport materials, poly(3,4-ethylenedioxythiophene) polystyrene sulfonate (PEDOT:PSS). Other organic electron transport materials include naphthalene diimides, perylene diimides, electron accepting diimides, electron accepting dianhydrides, pyromellitic anhydride, azaacene-based molecules, and bathocuproine (BCP).

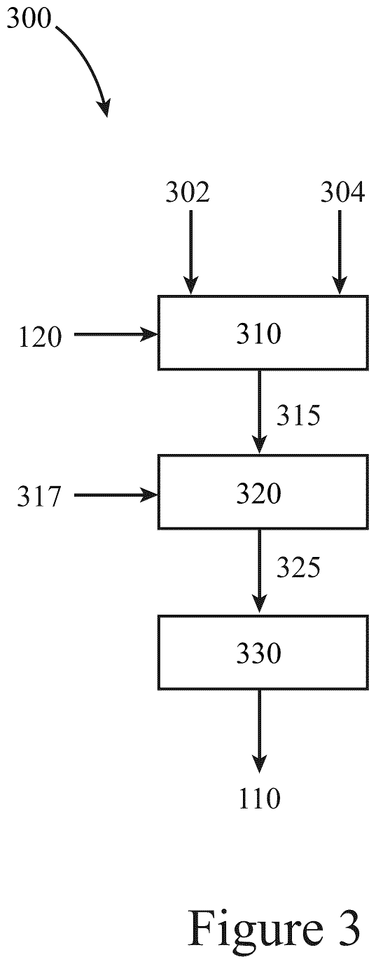

FIG. 3 illustrates a method 300 for synthesizing nanocrystals 110, according to some embodiments of the present disclosure. A method 300 may begin with the dissolving 310 of a first precursor 302, a second precursor 304, and a ligand 120 into a solvent to produce a first solution 315. In some embodiments of the present disclosure, the first precursor 302 may include at least one of BaI₂, BaCl₂, BaBr₂, barium (II) acetate, barium oxide, barium oleate, a hydrated form of any of the preceding, or a combination thereof. In some embodiments of the present disclosure, the second precursor 304 may include an oxide CdO, cadmium acetate, cadmium carbonate, cadmium oleate, cadmium chloride, cadmium bromide, cadmium iodide, or a combination thereof. In some embodiments of the present disclosure, the first and second precursors (302 and 304) may be dissolved in a non-polar, hydrophobic, organic solvent. Examples of such solvent include octadecene, toluene, hexane, octane, tetradecane, cyclohexane, chloroform, or combinations thereof.

Once the starting precursors have dissolved, a method 300 may proceed with the adding 320 of a third precursor 317 to the first solution 315 to form a second solution 325, and mixing the second solution such that, during the mixing, the nanocrystals are formed. In some embodiments of the present disclosure, the third precursor 317 may include at least one of a phosphine, an organo-silylphosphine, an aminophosphine, phosphorus, or a combination thereof. In some embodiments of the present disclosure, the third precursor 317 may be (TMSi)₃P. In some embodiments of the present disclosure, the nanocrystals 110 synthesized have a Zintl-phase having a composition as defined by AM₂X₂. In some embodiments of the present disclosure, a first precursor 302 may include A (e.g., Ba), a second precursor 304 may include M (e.g., Cd), and a third precursor 317 may include X (e.g., P). In some embodiments of the present disclosure, mixing may be achieved using mechanical mixing, sparging an inert gas, or a combination thereof. In some embodiments of the present disclosure, the stating precursors may be combined without mixing.

Referring again to FIG. 3, in some embodiments of the present disclosure, a method 300 for synthesizing nanocrystals may include, prior to the adding 320 step, removing water from the first solution 315 (removing step not shown). In some embodiments of the present disclosure, a method 300 for synthesizing nanocrystals 110 may further include, prior to the adding 320 step, heating the first solution 315 to a temperature between 20° C. to 300° C. or between 110° C. to 220° C. In some embodiments of the present disclosure, at least one of the adding 320 or mixing 330 may be completed in the presence of an inert gas (e.g., N₂). In some embodiments of the present disclosure, a first solution 315 may further include a ligand.

Thus, the present disclosure demonstrates the growth of size-controlled, high optical quality Zintl-phase colloidal quantum dots (QDs), e.g., BaCd₂P₂ and BaZn₂P₂, quantum dots, capable of emitting in the red spectrum of light and having high tolerance to defects. QDs are nanocrystals that exhibit quantum confinement effects, such as but not limited to size dependent optoelectronic properties. Amorphous nanocrystals are not QDs.

Zintl-phase materials are highly covalent polyanionic compositions having a MXⁿ⁻ (M=p-block or transition metal; X=electronegative elements: P, As, etc.) species interspersed by highly electropositive cations Aⁿ⁺ (A=alkali or alkaline earths). As described herein, QDs were successfully grown via hot-injection of a phosphorus precursor into a solution of solubilized Ba and Cd precursors.

As shown herein, the absorbance and photoluminescence of AM₂X₂ Zintl-phase nanocrystals are tunable via growth temperature with bandgaps ranging from 1.47 eV to 1.80 eV, depending on the size, which ranged in the experimental studies shown herein, between 3 nm and 9 nm based on electron microscopy. Selected area electron diffraction was used to determine that the BaCd₂P₂ nanocrystals crystallized in the P-3m1 space group, which was the same as the bulk material. Raman spectroscopy, powder X-ray diffraction, and X-ray fluorescence studies further confirmed the BaCd₂P₂ nanocrystals crystal structure matched that of the bulk material. The high optoelectronic quality was assessed by quantification of long-lived photoexcited carriers (~100 ns), as determined by time-resolved photoluminescence spectroscopy, and bright red visible emission with no designed surface passivation. Further, compositional control was demonstrated by the successful completion of a cation exchange reaction using ZnI₂ treatment to convert BaCd₂P₂ nanocrystals to Ba(CdₓZn₁₋ₓ)₂P2 nanocrystals, as verified by optical spectroscopy.

Growth of BaCd₂P₂ QDs: To synthesize BaCd₂P₂ quantum dots, a hot-injection method was used, as described above and illustrated in FIG. 3. This method included the following steps, specifically for the synthesis of BaCd₂P₂. However, the method can be easily adapted to produce other MA₂X₂ Zintl-phase materials, including MgZn₂P₂, CaZn₂P₂, SrZn₂P₂, BaZn₂P₂, MgCd₂P₂, CaCd₂P₂, SrCd₂P₂, BaCd₂As₂, MgZn₂As₂, CaZn₂As₂, SrZn₂As₂, BaZn₂As₂, MgCd₂As₂, CaCd₂As₂, SrCd₂As₂, and BaCd₂As₂. For the synthesis of BaCd₂P₂, mixtures of BaI₂·2H₂O (first precursor 302), CdO (second precursor 304), oleic acid (OA) (ligand 120), trioctylphosphine oxide (TOPO), an exemplary ligand, and octadecene (ODE) (solvent) were dried under vacuum on a Schlenk line, forming a first solution 315. The first solution 315 was then heated to 220° C. under N₂ and both powders of Ba and Cd precursor dissolved (step 310 in FIG. 3), with the BaI₂·2H₂O (dried at this stage to BaI₂) precursor taking longer than the CdO. The CdO was converted to Cd(oleate)₂ at this temperature which generated H₂O as a byproduct. The solution was then cooled to 120° C. and held under vacuum to ensure removal of this byproduct and any other excess H₂O. Failure to adequately dry the solution resulted in no growth of the QDs during the later steps.

After the Ba and Cd precursors were formed, the first solution 315 was brought to a specified reaction temperature (between 110° C. and 190° C.) while mixing with a Teflon coated stir bar and a mixture of stoichiometric tris(trimethylsilyl)phosphine, the third precursor 317 [(TMSi)₃P, 1:1 P:Cd] diluted in dry octadecene was added (step 320) by injection to the first solution 315. After the addition of the third precursor 317, there was an instantaneous color change to red in the resultant second solution 325, followed by a change from red to black during the growth with the speed of this color change depending on the temperature (approximately 5 seconds at a reaction temperature of 190° C. and approximately 1 minute at 110° C. to turn from red to black). The reaction was allowed to react while mixing with a Teflon coated stir bar 330 for reaction times from 10 seconds to 2 hours and cooled to room temperature (between 10° C. and 35° C.) by removing the resulting colloidal solution from heat.

The reaction to produce the BaCd₂P₂ nanocrystals is envisioned to proceed as follows:

$${Ba}^{2 +} + 2 {Cd}^{2 +} + 2 {( TM Si )}_{3} P \to {BaCd}_{2} {P}_{2} + 6 {( TM Si )}^{+}$$

with oleate (ligand), trioctylphosphine oxide (TOPO) (ligand), and unreacted trimethylsilyl groups as possible ligands terminating the surface. In some embodiments of the present disclosure, TOPO can be substituted by oleylamine (OLAM) or a mixture of the two.

The nanocrystals were then washed and centrifuged to remove the octadecene and unreacted precursors, once with methyl acetate (MeOAc), followed by two rounds of washing using acetone. The final washed and centrifuged nanocrystals were bound with the native growth ligands oleic acid and TOPO or oleic acid and oleylamine. This procedure was determined by testing various anti-solvents. For example, when MeOAc was used exclusively as an antisolvent (i.e. three rounds of MeOAc precipitation and centrifuging), the nanocrystals lost their colloidal stability suggesting the ligands were removed from the surface of the nanocrystals. When exclusively acetone, ethanol, or acetonitrile were used as the washing solvent, unreacted precursor from the growth was not effectively removed and would precipitate slowly from the nanocrystal solutions as a white gel-like species over time.

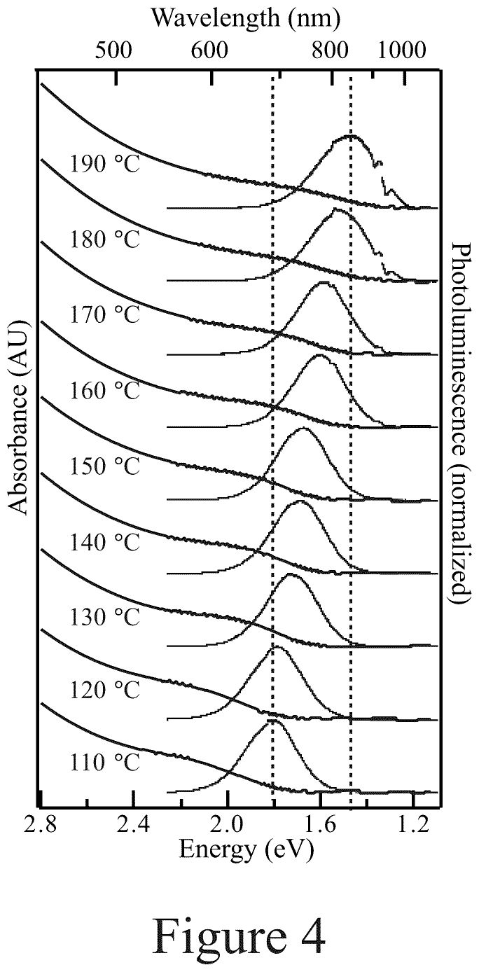

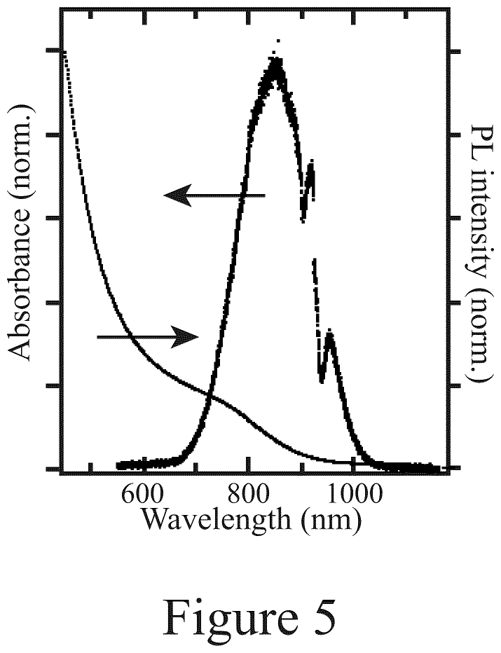

Characterization of BaCd₂P₂ nanocrystals: The BaCd₂P₂ quantum dot nanocrystals bound with oleic acid and TOPO ligands were characterized by steady-state absorption and PL. FIG. 4 illustrates the absorbance and PL spectra for nanocrystals synthesized at a temperature between 110° C. and 190° C. Synthesis temperatures below 190° C. produced confined QD nanocrystals with an observed blueshift in the absorbance and PL due to quantum confinement. In each case, there is a sloping onset of absorbance, which becomes sharper as the QD nanocrystals decreased in size from 9 nm (largest) to 3 nm (smallest). An exciton absorbance peak is not clearly observed in these room temperature measurements, possibly due to the exciton binding energy being low in these Zintl-phase semiconductors. Polydispersity of the QDs size is also a possible contributing factor to the sloping absorbance onset. At the highest temperature (190° C.), the absorption onset is approximately 1.43 eV and the PL position is 1.47 eV, in good agreement with the measurements on bulk BaCd₂P₂. Injection and growth at increased temperatures (up to 220° C.) did not result in further red-shifting of the band edge (see FIG. 5).

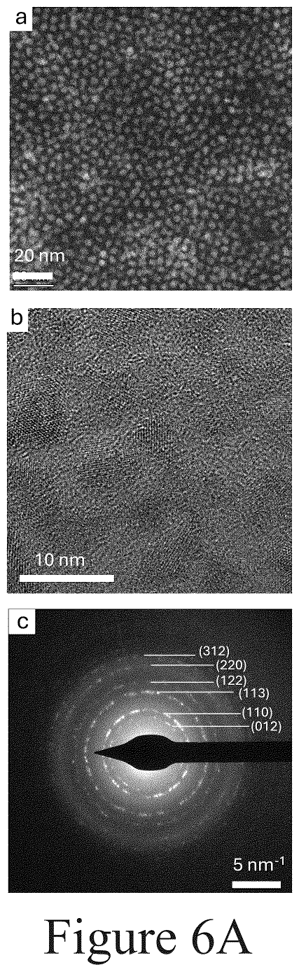

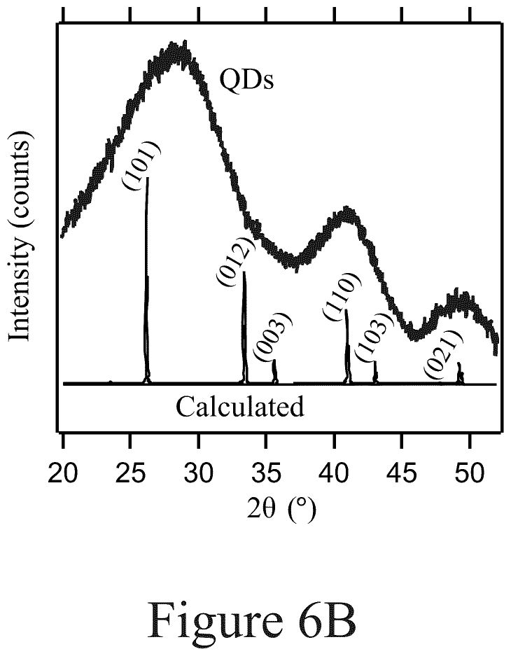

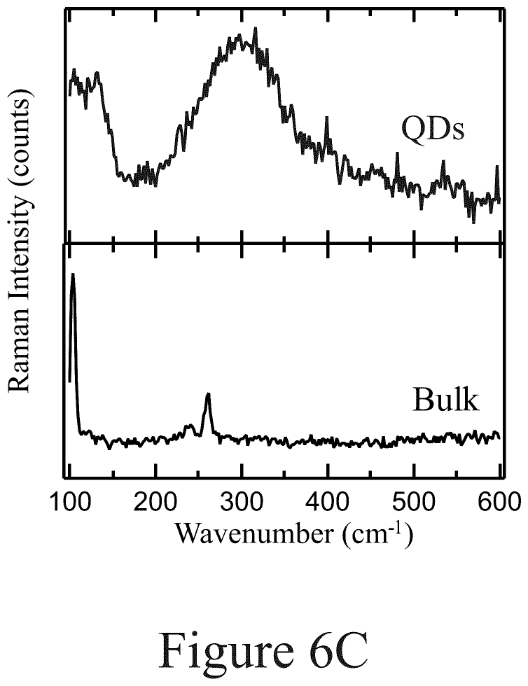

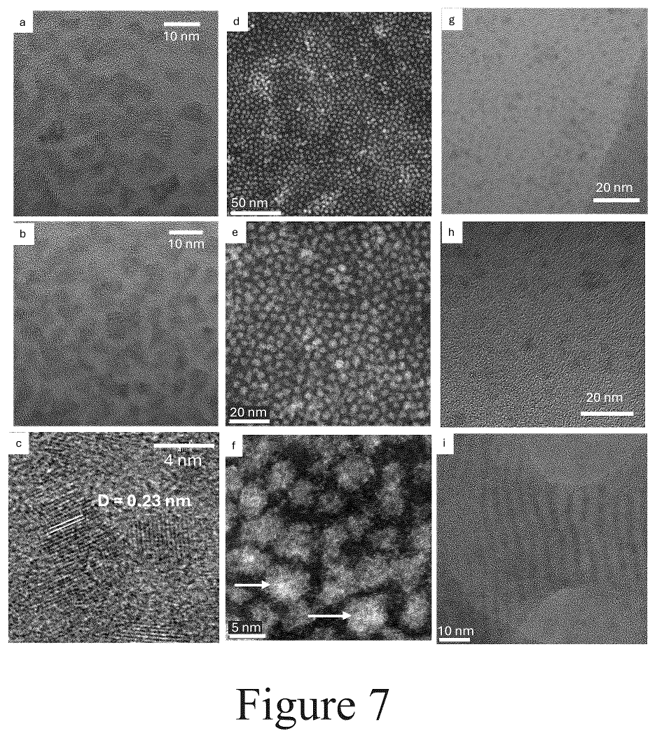

High Angle Annular Dark Field (HAADF) scanning transmission electron microscopy (STEM) and Transmission Electron Microscopy (TEM) images (see FIGS. 6A and 6B and FIG. 7) show small nanocrystals bound with oleic acid and TOPO ligands (ranging in size from 3 nm to 9 nm depending on growth temperature) with no clear faceting or crystal habit. The nanocrystals can be loosely described as spherical. This lack of faceting is possibly due to Ostwald ripening during growth, agglomeration of nanocrystals, or the trigonal symmetry of BaCd₂P₂ lacking robust surface energies for cubic or hexagonal facets (space group P-3m1). TEM on well washed nanocrystals showed lattice fringes indicating crystallinity in these samples. Lattice fringe distance observed was 0.23 nm which could correspond to the (110) reflection plane (see Panel (c) of FIG. 7). Selected Area Electron Diffraction (SAED) collected on the sample illustrated in Panel© of FIG. 6 was much more conclusive and could be successfully indexed to the same structure as bulk BaCd₂P₂ (see Table 1). Interestingly, before identifying adequate washing procedures to remove unreacted precursors, lattice fringes or clear SAED patterns in the microscopy were not observable.

TABLE 1
Measured and calculated lattice planes from Panel (c) of FIG. 7

| Measured | | Calculated | Difference |
|---|---|---|---|
| (Å) | (hkl) | (Å) | (Å) |
| 2.65 | (012) | 2.68 | 0.03 |
| 2.26 | (110) | 2.2 | 0.06 |
| 1.62 | (113) | 1.66 | 0.04 |
| 1.36 | (122) | 1.35 | 0.01 |
| 1.13 | (220) | 1.10 | 0.03 |
| 1.03 | (312) | 1.02 | 0.01 |

To further confirm the crystal structure of the produced BaCd₂P₂, the QD nanocrystals bound with oleic acid and TOPO ligands were dispersed in chloroform and drop cast onto silicon wafer substrates for powder X-Ray Diffraction (XRD), Raman spectroscopy, and X-Ray Fluorescence (XRF). The XRD pattern (see FIG. 6B) of particles showed broad features which can be assigned to the (101), (110), and (021) planes of bulk P-3m1 structure. The (101) does appear shifted or broadened to higher 2θ angles, which indicates a possible element of strain contracting the lattice in these samples to be characterized further in future experiments with a brighter X-ray source. Raman spectroscopy was compared between previously synthesized bulk BaCd₂P₂ powders and the BaCd₂P₂ QD nanocrystals (see FIG. 6C). Bulk BaCd₂P₂ has two sharp Raman peaks at 104 cm⁻¹ and 262 cm⁻¹. The BaCd₂P₂ QD nanocrystals grown at 190° C. showed two broadened peaks centered at 120 cm⁻¹ and 300 cm⁻¹. This blueshift in the Raman peaks is expected with dimensionality confinement and the presence of two peaks in both samples helps confirm that studied samples are Zintl-phase BaCd₂P₂ QD nanocrystals. XRF was used to determine that there was a 41:60 Ba:Cd ratio, close to the expected 2:1. This slight deviation could be due to Ba—P surface termination in these high surface area QD nanocrystals. The culmination of these results, as well as the SAED, allows one to conclude that QD nanocrystals synthesized are the BaCd₂P₂ Zintl-phase initially targeted.

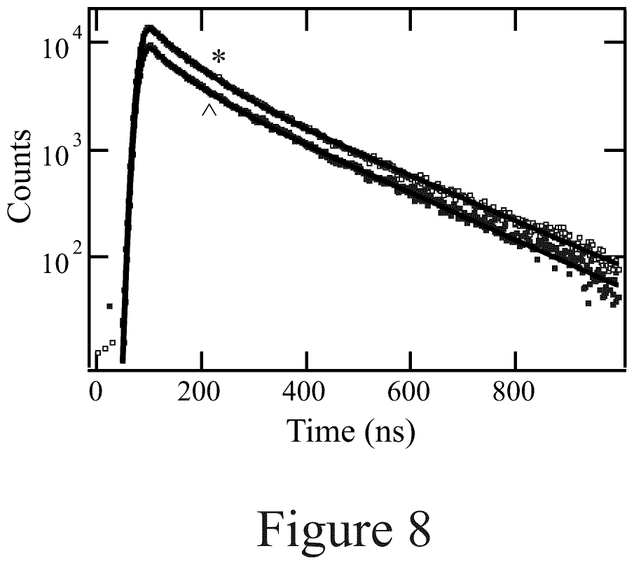

Carrier recombination lifetimes of the BaCd₂P₂ bound with oleic acid and TOPO ligands were evaluated via time-resolved photoluminescence (TRPL) (see FIG. 8). Fitting the TRPL spectra to a biexponential decay convolved with a Gaussian instrument response function (σ_{IRF}=10.5 ns) results in lifetimes of 61 ns (25% of integrated emission (IE)) and 200 ns (75% IE) (power=7.0 μW) and 70 ns (33% IE) and 210 ns (67% IE) (power=0.16 μW). The decay is distinctly biexponential but not distinctly power-dependent to suggest bimolecular recombination. Rather, the biexponential decay indicates that there are two populations decaying at their own independent rate. This could be due to polydispersity in the QD size or heterogeneity in the density of surface states, providing different overall decay rates for different QDs. This ~160 ns weighted average lifetime is potentially suitable for a range of optoelectronic applications. This ~100 ns lifetime is suitable for solar cells as well as light emitting diode (LED) applications.

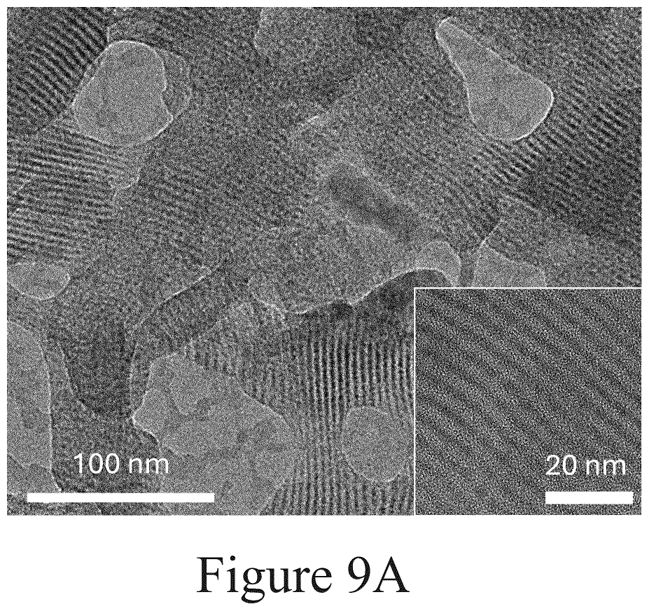

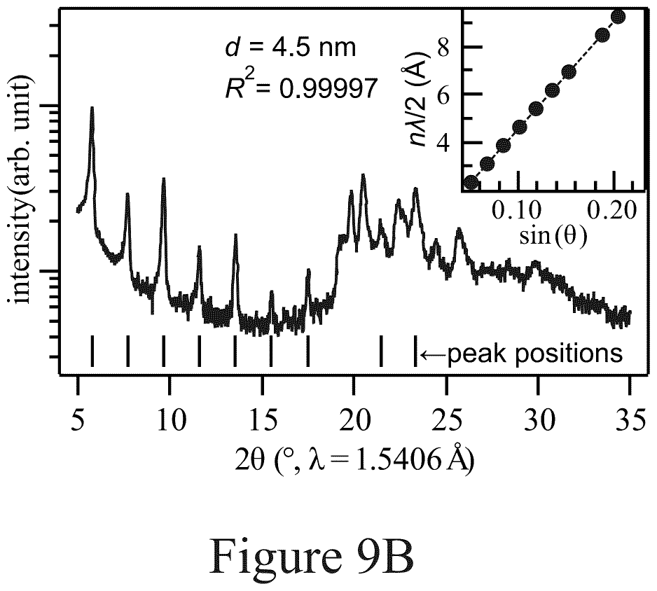

An interesting phenomenon is the self-assembly of these BaCd₂P₂ QD nanocrystals into superlattice-like structures. Self-assembled QD superlattices open opportunities for exotic phenomena such as inter QD optical coupling, superfluorescence, and enhanced thermoelectrics. FIG. 9A illustrates a TEM micrograph of a superlattice-like structure of the QD nanocrystals bound with oleic acid and TOPO ligands stacked with ligand shell organics in between. Initially, the structure looked like nanowires or on-edge nanoplates, but closer inspection reveals individual particles that assembled in a linear array (see the inset of FIG. 9A). X-ray diffraction (see FIG. 9B) shows the prominence of this remarkably ordered array of these BaCd₂P₂ QD nanocrystals bound with oleic acid and TOPO ligands. A fit of the diffraction peaks reveals 4.5 nm spacing, in excellent agreement with electron micrographs. Some of the peaks in the 19°-26° range, corresponding to d-spacings from ~3.4 Å-4.6 Å, drastically reduce the fit quality, presumably because they arise from internal QD and/or ligand spacings, so are not included in the superlattice fit. In very homogenous colloidal quantum dots, self-assembly of particles upon drying is not uncommon. What is interesting in these self-assembled BaCd₂P₂ QD nanocrystals is that the structure looks like a true superlattice, i.e. 2D stacked ordering instead of 3D arrays typically observed.

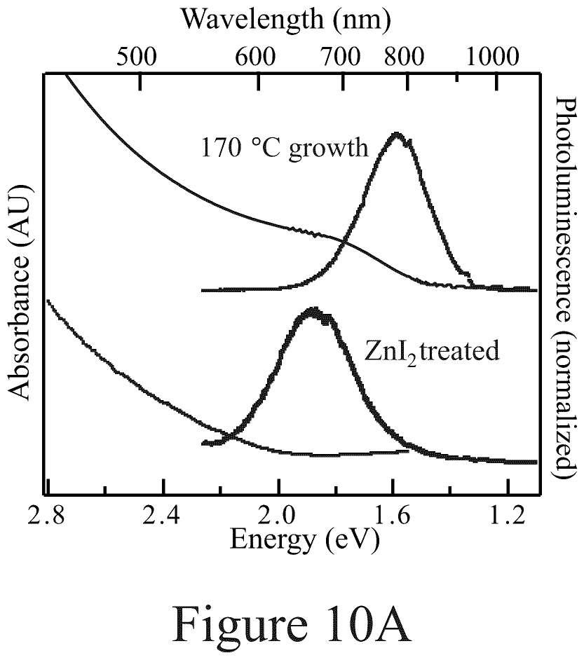

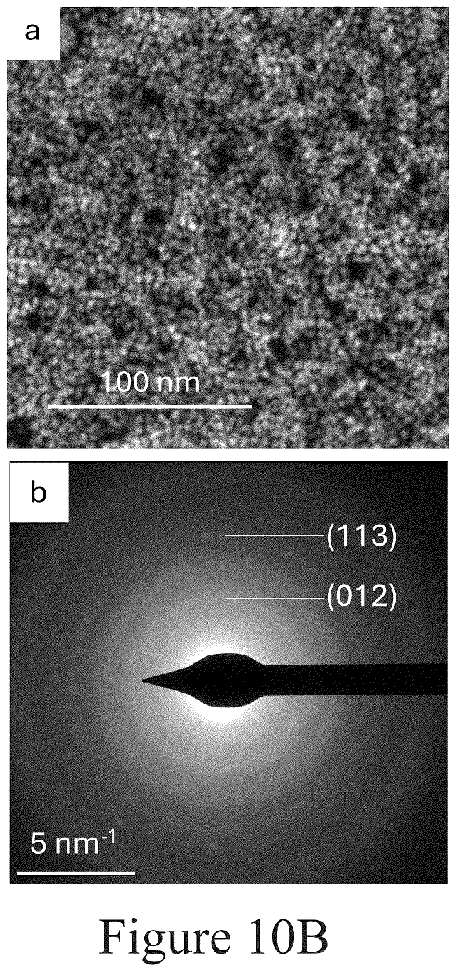

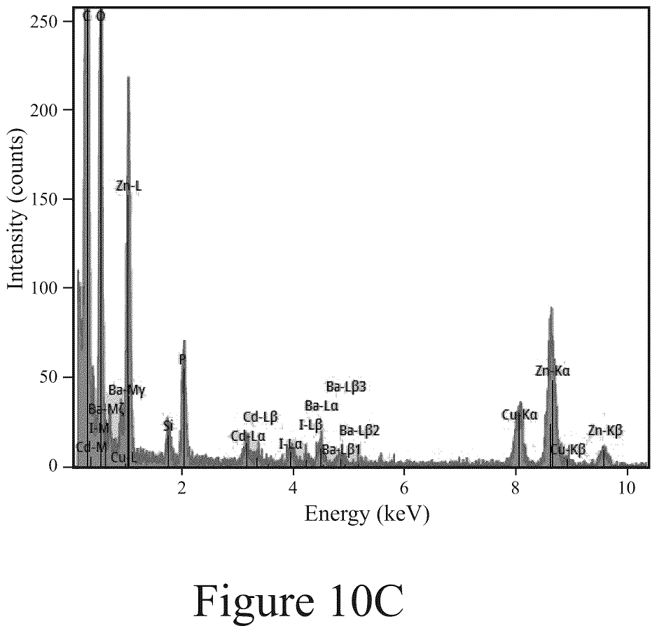

The possibility of cation exchange reactions with BaCd₂P₂ were studied. Owing to the large surface-to-volume ratio in QD nanocrystals, cation exchange reactions can be extremely rapid. This allows for optoelectronic property tuning and reducing Cd content. Solid ZnI₂ powders were added to BaCd₂P₂ QD nanocrystals bound with oleic acid and TOPO ligands bound with oleic acid and TOPO ligands in toluene and stirred overnight to target Ba(Cd₁₋ₓZnₓ)₂P₂. There was a noticeable change in the color of solution, from black to red. FIG. 10A illustrates the resulting shifting of the PL from an initial 1.60 eV to 1.88 eV. This is higher energy than our smallest particles emission wavelength (3 nm, 1.8 eV), providing strong evidence this is due to Zn exchange to form Ba(Cd₁₋ₓZnₓ)₂P₂. Panel (a) of FIG. 10B illustrates a TEM image of the Ba(Cd₁₋ₓZnₓ)₂P₂ QD nanocrystals and Panel (b) of FIG. 10B illustrates electron diffraction results. The lattice spacing calculated from the electron diffraction decreases as compared to BaCd₂P₂ (Table 2 and 3). Moreover, FIG. 10C illustrates the energy dispersive x-ray spectra of the Ba(Cd₁₋ₓZnₓ)₂P₂ with clear Zn-L and Zn-kα lines.

TABLE 2
Measured lattice distances in ZnI₂ exchanged BaCd₂P₂ QDs.

| | | BaCd₂P₂ | |
|---|---|---|---|
| Measured | Proposed | Calculated | Difference |
| (Å) | (hkl) | (Å) | (Å) |
| 2.50 | (012) | 2.68 | 0.18 |
| 1.57 | (113) | 1.66 | 0.09 |

TABLE 3
Calculated lattice constants from electron
diffraction on ZnI₂ BaCd₂P₂ QDs.

| | Neat QD | ZnI₂-treated |
|---|---|---|
| | BaCd₂P₂ | QD BaCd₂P₂ |
| a, Å | 4.40 | 4.10 |
| c, Å | 7.55 | 7.30 |
| V, Å³ | 126.6 | 106.3 |

BaI₂·2H₂O was the only Ba precursor that successfully dissolved in the OA/TOPO/ODE or OA/OLAM/ODE solution at 220° C. (OA=oleic acid, TOPO=trioctylphosphine oxide, ODE=1-octadecene, OLAM—oleylamine). BaO, Ba(acetate)₂ and BaCO₃ did not dissolve under these conditions or even higher temperatures (up to 270° C.). BaI₂·2H₂O would not dissolve with only OA present and required TOPO or OLAM to solubilize. Interestingly, experiments showed Ba(acetate)₂ can be solubilized by addition of NaI to the OA/TOPO/ODE precursor solution, possibly indicating the iodide is participating in coordination of the solubilized species, not simply a convenient barium salt for Ba-oleate formation. This was abandoned in favor of BaI₂ salts to avoid unintentional Na inclusion in the QD nanocrystals. Based on the above observations it may be inferred that a BaI₂·xOLAM species is what is formed as the QD nanocrystal precursor solution (as noted OLAM can be substituted for TOPO). Anhydrous BaI₂ as a starting material was also successfully solubilized with this preparation, suggesting water is not essential for solubilizing the Ba salt. However, the anhydrous Ba salt is less convenient for preparation of stoichiometrically accurate Ba concentrations when preparing our reactions in ambient atmosphere (as water may be picked up by the BaI₂ during weighing) and the hydrate was removed in-situ to seemingly great effect, as described above. Other halide salts may also be suitable, with potential to modify the precursor reactivity.

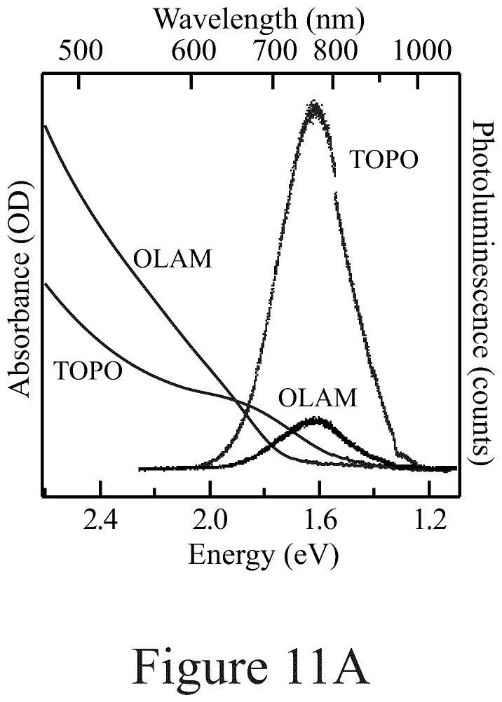

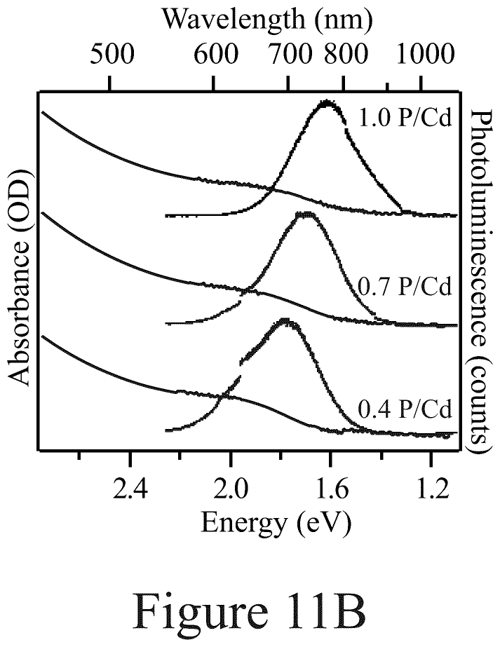

A variety of growth conditions were evaluated. First, the effects of TOPO vs. OLAM as a ligand during growth were studied. As can be seen in FIG. 11A, there is no shifting in the PL spectra indicating similar growth dynamics and particle size. However, there is a much brighter PL emission intensity for the TOPO grown nanocrystals. This may indicate either higher quality particles or better surface passivation with the TOPO ligand. The phosphorus precursor concentration was also evaluated. The anion precursor during nanocrystal growth can control aspects of the growth such as nucleation. For example, in chalcogenide nanocrystal synthesis, the anion concentration and injection rate affect the size dispersity, yield, and amount of time before Ostwald ripening begins to occur in the growth. In an experiment, “lean” anion injection of ratios 0.4, 0.7, and 1.0 (Cd/(TMSi₃)P molar ratio) were used. FIG. 11B shows there is blue shifting with decreasing (TMSi)₃P/Cd ratios, indicating smaller nanocrystals were grown. There is also an increase in the PL width and the shape becomes asymmetric. Based on these observations, the highest quality BaCd₂P₂ QD nanocrystals were grown with TOPO and stoichiometric (TMSi)₃P.

The stoichiometric ratio of Ba:Cd during growth was not extensively explored. A 3:1 Ba:Cd precursor ratio was tested for one growth and there appeared to be no formation of a visible/NIR absorbing compound, as indicated by the lack of color change after injection of the phosphorus precursor.

The ligand chemistry was lightly explored. As oleic acid is a protic ligand, excess oleic acid resulted in no reaction due to quenching of the (TMSi₃P). The other ligand species can have similar deleterious effects, either from purity or other side reactions. Attempts with large excess of oleylamine also resulted in no growth of nanocrystals for unclear reasons. Thus, OA was used only in slight excess molar ratio with CdO/BaI₂ and TOPO or OLAM were 1.5 molar ratio with BaI₂·2H₂O; only enough excess to ensure solubilization of the precursors. The reaction seemed scalable and increasing the reaction molarity three-fold (while maintaining the ODE 8 mL volume) yielded the same growth as the lower concentration.

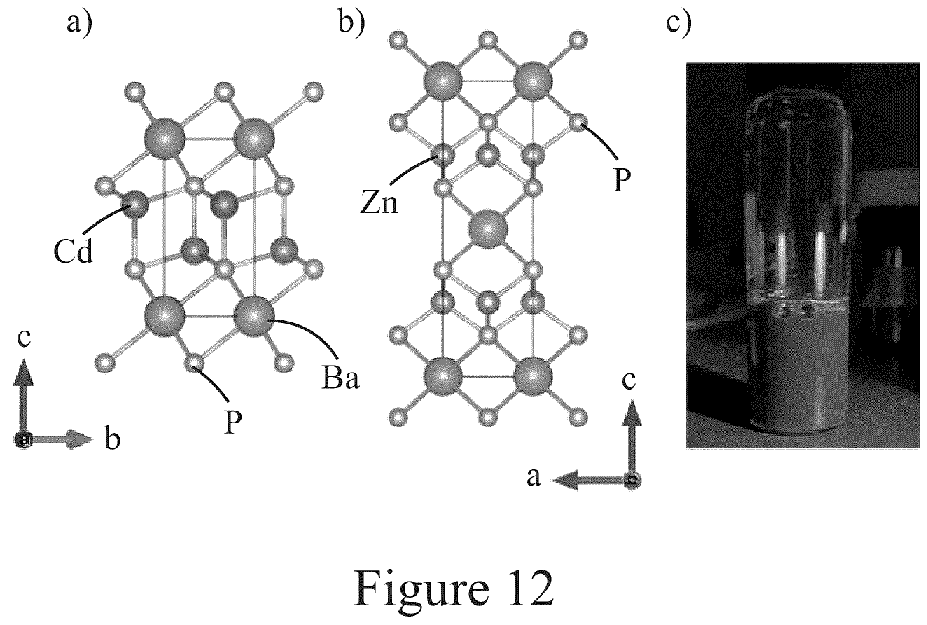

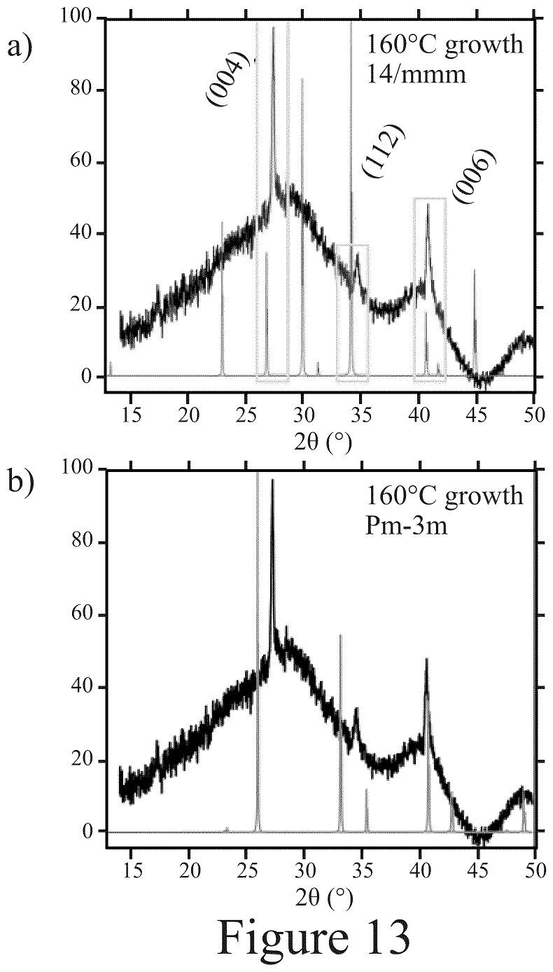

The growth to produce colloidally stable AM₂P₂ nanocrystals with bright photoluminescence (PL) (see Panel (c) of FIG. 12) proceeds rapidly at room temperature with no further surface modifications (i.e. no shell). The absorption onset and PL emission is tunable based on the growth temperature as different sized nanocrystals are accessed. Furthermore, the choice of M species between Zn and Cd allows further tuning of the optical features. XRD suggests that these form in the I4/mmm phase from the growth (see Panels (a and b) of FIG. 12). X-ray diffraction spectra shown in FIG. 13 shows the BaCd₂P₂ samples grown at 160° C. form in the I4/mmm phase previously observed in the related BaZn₂P₂ composition. X-ray fluorescence spectroscopy indicates the Ba and Cd are in a 1:2 ratio (37.63:62.37) as expected.

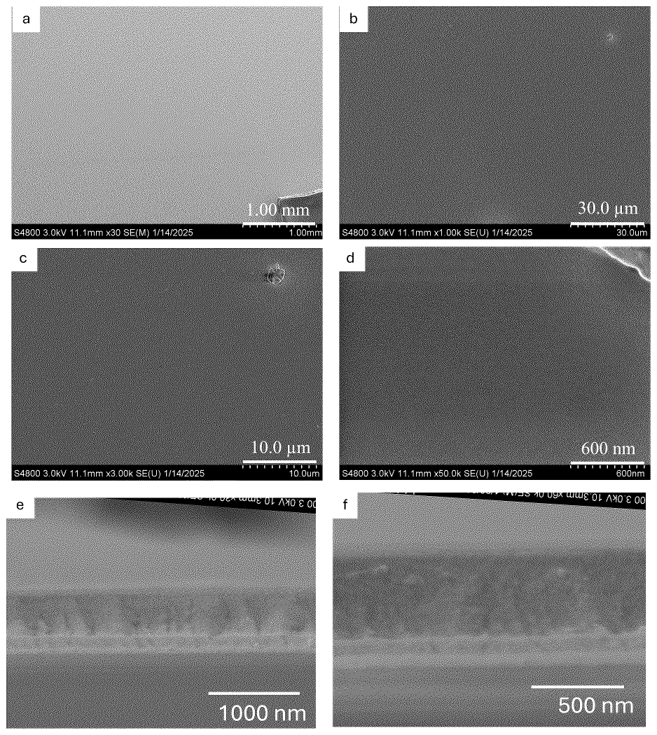

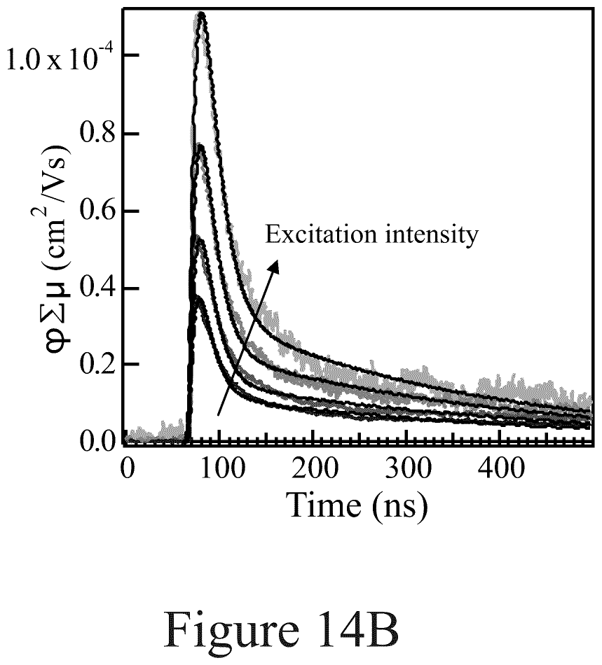

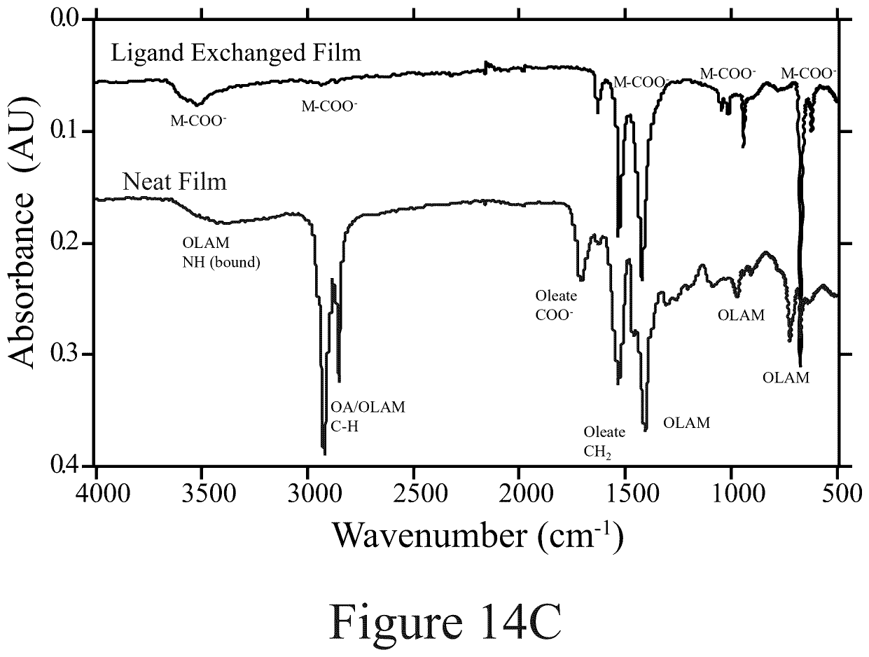

A key experiment in the development of novel semiconductors is the ability to synthesize layers for potential integration into optoelectronic platforms, like that illustrated in FIG. 2. Layers of QD nanocrystals can be spin coated from solution, yet with native ligands, these layers are challenging to grow into optically dense layers (typically <0.1 optical density (OD)). As such, previously developed solid-state ligand exchange methods were utilized to remove long chain ligands and replace them with small metal anion salts. This allowed for repeated spin coating without removal of the previously deposited underlying layer. In brief, BaCd₂P₂ QD nanocrystals bound with oleic acid and oleylamine ligands in octane were spin cast onto glass slides followed by dipping into saturated cadmium (II) acetate (Cd(Ac)₂) solutions as the ligand exchange salt. This results in the removal of native ligands oleic acid and oleylamine being replaced by acetate, Cd, or some combination of the two as indicated by the FTIR (below) as well as resulting insolubility of the films in toluene (where BaCd₂P₂ QD nanocrystals with native ligands would remain soluble). The layers were characterized by scanning electron microscopy (SEM) which showed a smooth, pinhole free surface across multiple magnifications. Panels (a-d) of FIG. 14A illustrate top-down SEM views and Panels (e and f) illustrate cross-section SEM views of smooth layers with ~500 nm thickness corresponding to 8 repeated spin coating cycles. Fourier transformed infrared spectroscopy (FTIR) was performed on neat QDs (i.e. no ligand exchange) and the ligand-exchanged QD, both scraped off substrates for the measurement. FTIR shows the removal of long chain species and replacement of them with acetate indicating the ligand exchange was successful (see FIG. 14C). This provides a basic framework to expand upon for BaCd₂P₂ QD layer formation.

Time-Resolved Microwave Conductivity (TRMC) was used to probe photoinduced charge generation and recombination dynamics within BaCd₂P₂ QD nanocrystal layers prepared with an OD_{500 nm}>0.6 by repeating the solid-state exchange procedure 8 times. In most inorganic semiconductors, the yield of electron-hole pairs per absorbed photon (φ) can be assumed to be 1 in GHz-frequency TRMC measurements, making these quantitative assessments of the carrier mobility (diffusivity) on a 100 ps timescale. FIG. 14B illustrates photoconductivity transients and their bi-exponential fits over an order of magnitude excitation intensity. The average weighted lifetime (t) is ca. 60 ns, with a longer time component of ~300 ns corresponding to ca. 17% weight of the fit, and an intensity-independent decay profile. The yield mobility (μ) product φΣμₜ₌₀ is 2-4×10⁻⁴ cm²V⁻¹s⁻¹, which appears to be much smaller than that measured previously for powders of BaCd₂P₂. This result suggests that the TRMC signal originates primarily from intra-QD carriers (i.e. confined within a QD), which dramatically curtails the measured mobility. Calculations based on the size of the QD (5 nm) suggest that the intrinsic mobility of the material is 10 cm²V⁻¹s⁻¹, explaining this apparent discrepancy between bulk and QDs. Cd(Ac)₂ ligands are adequate for providing a pathway for layer formation, but other ligand removal (such as sintering) or exchange procedures are hypothesized to yield longer lifetimes and higher inter-grain mobilities.

Following the work to develop layer processing, BaCd₂P₂ QD nanocrystals were used in a layer film photovoltaic architecture to demonstrate semiconductor behavior and potential for photodetectors or solar energy conversion. The initial focus was optimization of the BaCd₂P₂ QD nanocrystal layer beyond the initial Cd(Ac)₂ exchange process. To this end, several treatments for surface ligand exchange were studied. The quality of the ligand exchange was determined simply by washing with toluene after the attempted ligand exchange i.e., if the ligands exchanged effectively, the BaCd₂P₂ QD nanocrystals will no longer be solubilized in toluene. QD solutions (~100 mg/mL in octane) were spin coated onto 1×1 cm² glass substrates followed by dipping into saturated solutions of ligand exchange salts in methyl acetate.

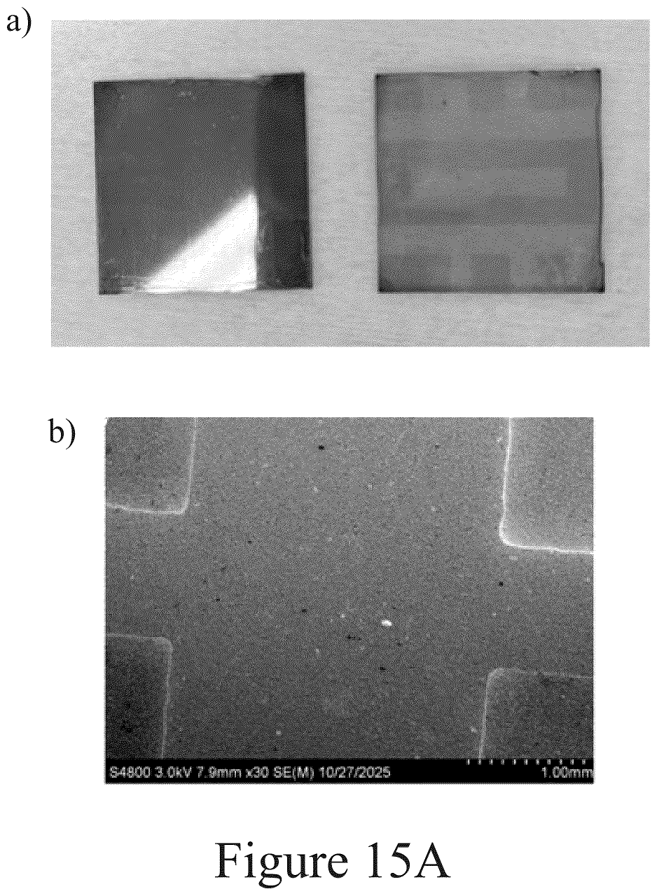

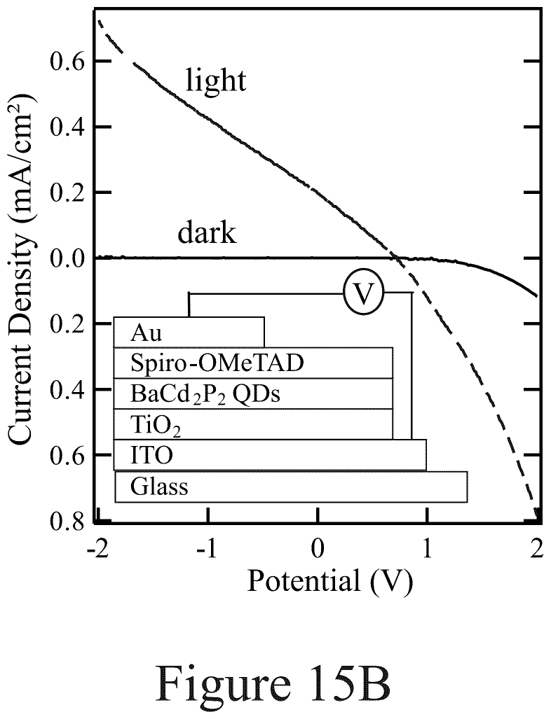

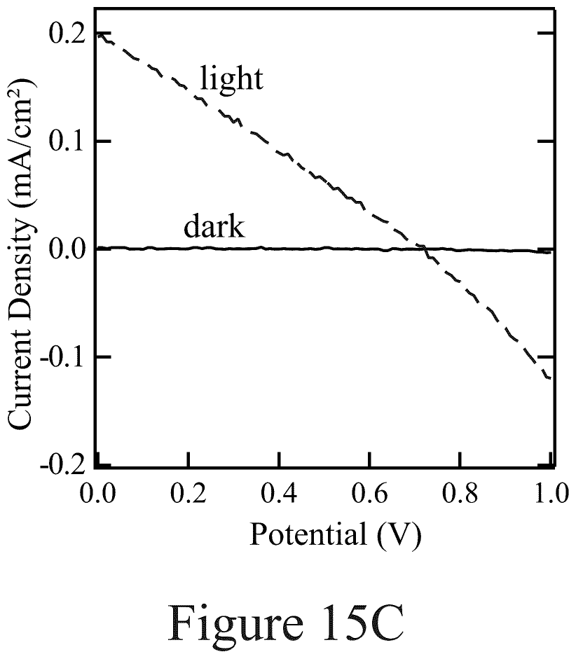

Ligand exchange salts Pb(NO₃), Zn(Ac)₂, (MA)I (MA=methylammonium), CrCl₃, BiI, Pb(Ac)₂, RbBr, CsBr, PbI₂, MABr, PbB₂, SnF₂, CuBr₂, (FA)I (FA=formamidinium), (FA)(Ac), Bi(Ac)₃, Cd(Ac)₂/CdI₂, and Sr(NO₃)₂ all failed to build up layer thickness or were washed off with toluene, demonstrating they are poor ligand exchange agents under the conditions tested. SbBr₃, SbI₃, ZnI₂, ZnBr₂, methythiocyanate (MeSCN), oxalic acid, and MgBr₂ all showed layer build up with no removal following toluene treatment. Oxalic acid was abandoned due to dramatic color change in the film following treatment. An example of a good layer build up versus poor is shown in Panel (a) of FIG. 15A.

Devices were then fabricated in the following architecture: Glass/ITO/BaCd₂P₂ QDs/Spiro-OMeTAD/Au, where Spiro-OMeTAD is (2,2′,7,7′-tetrakis(N,N-di-p-methoxyphenylamine)-9,9′-spirobifluorene) (see inset of FIG. 15B). SbBr₃ and SbI₃ showed zero photo response (though much more conductive), suggesting some metallic behavior, possibly from the unintended reduction of metals in the film. MeSCN and MgBr2 did not build layers adequately and the layer flaked or washed off during Spiro-OMeTAD deposition (where chlorobenzene is used). ZnBr₂ was the most effective and reproducible for depositing films, while maintaining semiconducting behavior as indicated by PL, excitonic feature in the absorbance and photoconductivity. ZnBr₂ layers were smooth and pin-hole free as illustrated in Panel (b) of FIG. 15A. Devices with ZnBr₂ showed an open-circuit voltage (V_{oc}) of 0.72 and a short-circuit current (Jsc) was 0.2 mA/cm² (see FIGS. 15B and 15C).

### Materials and Methods:

All chemicals were used without further purification. BaI₂·2H₂O (98%), CdO (99.99% trace metal basis), ZnI₂ (≥98%), (TMSi)₃P (95%), 1-octadecene (for synthesis, ≥91.0%), oleic acid (technical grade, 90%), trioctylphosphine oxide (ReagentPlus®, 99%), oleylamine (technical grade, 70%), and methyl acetate (MeOAc, ReagentPlus®, 99%) were purchased from Sigma Alrdich. Toluene (ACS grade, 99.5%) was purchased from oakwood chemical. Acetone (ACS, 99.5%) was purchased from VWR.

Synthesis of BaCd₂P₂ QDs: A dried 25 mL three-neck round bottom flask was charged with 73 mg (0.17 mmol) of BaI₂·2H₂O, 44 mg CdO (0.34 mmol), 8 mL octadecene (ODE), 200 mg trioctylphosphine oxide (TOPO), and 300 μL oleic acid (OA). The mixture was dried on the Schlenk line (close to 100 mTorr) at RT until all bubbling stopped (<30 minutes) then the temperature was raised to 115° C. and held for at least 1 hour. Afterward, the atmosphere in the flask was switched to N₂ and the mixture was heated to 220° C. and held for 30 minutes ensuring complete precursor dissolution. The solution was then cooled to 120° C. and dried under vacuum again for at least 1 hour. The solution was then transferred back to a nitrogen atmosphere and held at the desired temperature, and (TMSi)₃P (98 μL, 0.34 mmol) dissolved in dry ODE (1:5 ratio) was swiftly injected and allowed to react for 30 minutes followed by removal from heat and cooling to RT with no intentional quenching. For experiments done with OLAM, 0.5 mL of OLAM was used in the growth. Other deviations are noted in the text.

Purification of BaCd₂P₂ QDs: After the growth was complete and the reaction was cooled to RT, the mixture (typically ~10 mL of mixture) was transferred to a 50 mL conical tube. MeOAc was added in a 1:1 ratio and centrifuged at 5K RPM for 5 minutes. The orange/brown supernatant was discarded, and the black precipitate was resuspended in 10 mL of toluene and then crashed out with 20 mL of Acetone, followed by centrifuging at 10K RPM for 5 minutes. This acetone step was repeated, and the final precipitate was either resuspended in toluene or kept as a dry powder.

UV-VIS-NIR Steady State Spectroscopy: BaCd₂P₂ QDs dispersed in toluene were diluted and UV-VIS-NIR absorption spectra were collected with a Cary 6000i spectrometer.

Photoluminescence (PL): PL spectra were acquired using a Horiba spectrophotometer equipped with a 405 nm laser with a collection time of 0.5 s and 600 line/mm grating.

X-Ray Fluorescence Spectroscopy (XRF): measurements were recorded using a Rh anode at 50 keV and spectra were modeled as a BaCd₂P₂ composition.

Raman Spectroscopy: Raman spectra were recorded using the Renishaw in Via™ confocal system with a 532 nm laser line and the 20× long working distance objective lens equipped with an 1800 lines mm⁻¹ grating.

Time-Resolved Photoluminescence (TRPL): Time-resolved photoluminescence data was collected using a Hamamatsu Streak Camera (300-900 nm, C10910-04) with an NKT supercontinuum fiber laser (SuperK EXU-6-PP) routed to an acousto-optic tunable filter (SuperK Select). The samples were photoexcited at 500 nm with a rep rate of approximately 0.691 MHz. The samples were loaded into a 1 cm cuvette and excited at a right-angle geometry to the detector to minimize scattering. Panel (b) of FIG. 5 illustrates an averaged slice from 710-720 nm of the data located around the PL maxima.

Electron Microscopy: Images were taken on uc-lacey carbon grids. The grid was prepared by diluting the QDs in toluene until the color was barely visible and adding one drop via a Pasteur pipette onto the grid. The grid was then dried at 0.1 Torr overnight before loading into the electron microscopes. Most samples were briefly plasma cleaned in a mixture of 5% H2+95% N2 prior to imaging. The samples were examined in either a Thermo Fisher Spectra 200 cold field emission gun (FEG) Cs-corrected S/TEM or a FEI Tecnai F20 UltraTwin FEG STEM, both operated at 200 kV.

X-ray Diffraction: Samples were prepared on Si wafer for X-ray diffraction characterization by drop casting QDs dispersed in toluene. In samples that exhibited the superlattices, the sample was prepared from drop casting the QDs dispersed into chloroform. The presence of the ordered superlattice in electron microscopy from samples prepared from toluene suggest the chloroform is not essential.

### Examples

Example 1. A composition comprising: a nanocrystal comprising: a Zintl-phase, a P-3 ml space group, a diameter between 2 nm and 25 nm, and a bandgap between 0.6 eV and 2.2 eV.

Example 2. The composition of Example 1, wherein: the nanocrystal has a stoichiometry as defined by AM₂X₂, wherein: M comprises at least one of a p-block element, a transition metal, or a combination thereof, X comprises a highly electronegative element, and A comprises at least one of an alkali element, an alkaline earth element, or a combination thereof.

Example 3. The composition of Example 1 and/or Example 2, wherein M comprises at least one of cadmium, zinc, mercury, or a combination thereof.

Example 4. The composition of any one of Examples 1-3, wherein X comprises at least one silicon, nitrogen, phosphorus, arsenic, antimony, bismuth, or a combination thereof.

Example 5. The composition of any one of Examples 1-2, wherein A comprises at least one of barium, calcium, beryllium, strontium, magnesium, or a combination thereof.

Example 6. The composition of any one of Examples 1-2, wherein the nanocrystal has a stoichiometry comprising at least one of BaCd₂P₂, CaZn₂P₂, SrCd₂P₂, ACd₂As₂, AZn₂As₂, or a combination thereof.

Example 7. The composition of any one of Examples 1-6, wherein the stoichiometry is selected from the group consisting of BaCd₂P₂, CaZn₂P₂, or a combination thereof.

Example 8. The composition of any one of Examples 1-1, further comprising: a ligand, wherein: the ligand is ionically bonded to the nanocrystal.

Example 9. The composition of any one of Examples 1-8, wherein the ligand comprises an organic ligand, an inorganic ligand, or a combination thereof.

Example 10. The composition of any one of Examples 1-9, wherein the organic ligand comprises at least one of oleate, trioctylphosphine oxide, a carboxylate, an organo-amine, an organo-phosphine, or a combination thereof.

Example 11. The composition of any one of Examples 1-10, wherein the organic ligand comprises at least one of oleic acid, sodium oleate, oleylamine, trioctylphosphine, or trioctylphosphine oxide, or a combination thereof.

Example 12. The composition of any one of Examples 1-9, wherein the inorganic ligand is a halide.

Example 13. The composition of any one of Examples 1-12, wherein the halide comprises at least one of chloride, bromide, iodide, or a combination thereof.

Example 14. The composition of any one of Examples 1-1, wherein the nanocrystal is absent a ligand.

Example 15. The composition of any one of Examples 1-1, wherein the bandgap is between 1.4 eV and 1.9 eV.

Example 16. The composition of any one of Examples 1-1, wherein the diameter is between 3 nm to 9 nm.

Example 17. The composition of any one of Examples 1-1, comprising a recombination lifetime of greater than 100 ns to 1000 ns.

Example 18. The composition of any one of Examples 1-1, comprising the ability to exchange a first element for a second element by cation exchange, wherein the first element comprises cadmium and the second element comprises zinc.

Example 19. The composition of any one of Examples 1-18, wherein the first element is cadmium and the second element is zinc.

Example 20. The composition of any one of Examples 1-1, wherein the nanocrystal has a morphology comprising at least one of a quantum dot, a nanowire, a nanoplate, an amorphous morphology, or a combination thereof.

Example 21. The composition of any one of Examples 1-1, further comprising stability when immersed in liquid water at 25° C.

Example 22. A device comprising: a layer comprising a nanocrystal, wherein the nanocrystal comprises: a Zintl-phase; a P-3m1 space group; a diameter between 2 nm and 25 nm; and a bandgap between 0.6 eV and 2.2 eV, wherein: the layer has a thickness between 3 nm and 3 μm or between 3 nm and 1000 nm or between 3 nm and 500.

Example 23. The device E22, further comprising: a first charge transport layer (first CTL); and a second CTL, wherein: the layer comprising a nanocrystal is positioned between the first CTL and the second CTL.

Example 24. The device of Example 22 and/or Example 23, wherein the first CTL comprises a hole-transport material.

Example 25. The device of any one of Examples 22-23, wherein the first CTL comprises an electron-transport material.

Example 26. A method comprising: dissolving a first precursor and a second precursor in a first solution; adding a third precursor to the first solution to form a second solution; and mixing the second solution, wherein: during the mixing, the nanocrystals are formed, the nanocrystals are characterized by a Zintl-phase having a composition as defined by AM₂X₂, the first precursor comprises A (e.g., Ba), the second precursor comprises M (e.g., Cd), and the third precursor comprises X (e.g., P).

Example 27. The method of Example 26, wherein prior to the adding, removing water from the first solution.

Example 28. The method of Example 26 and/or Example 27, wherein prior to the adding, heating the first solution to a temperature between 20° C. to 300° C. or between 110° C. to 220° C.

Example 29. The method of any one of Examples 26-28, wherein at least one of the adding or mixing is completed in the presence of an inert gas (e.g., N₂).

Example 30. The method of any one of Examples 26-29, wherein the first solution further comprises a ligand.

Example 31. The method of any one of Examples 26-30, wherein the first precursor comprises at least one of BaI₂, BaCl₂, BaBr₂, barium (II) acetate, barium oxide, barium oleate, a hydrated form of any of the preceding, or a combination thereof.

Example 32. The method of any one of Examples 26-31, wherein the second precursor comprises an oxide CdO, cadmium acetate, cadmium carbonate, cadmium oleate, cadmium chloride, cadmium bromide, cadmium iodide, or a combination thereof.

Example 33. The method of any one of Examples 26-32, wherein the third precursor comprises at least one of a phosphine, an organo-silylphosphine, an aminophosphine, phosphorus, or a combination thereof.

Example 34. The method of any one of Examples 26-33, wherein the third precursor comprises (TMSi)₃P.

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

The foregoing discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations, may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

What is claimed is:

1. A composition comprising:
a nanocrystal comprising:
a Zintl-phase,
a P-3m1 space group,
a diameter between 2 nm and 25 nm, and
a bandgap between 0.6 eV and 2.2 eV.

2. The composition of claim 1, wherein:
the nanocrystal has a stoichiometry as defined by AM₂X₂, wherein:
M comprises at least one of a p-block element, a transition metal, or a combination thereof,
X comprises a highly electronegative element, and
A comprises at least one of an alkali element, an alkaline earth element, or a combination thereof.

3. The composition of claim 2, wherein M comprises at least one of cadmium, zinc, mercury, or a combination thereof.

4. The composition of claim 2, wherein X comprises at least one silicon, nitrogen, phosphorus, arsenic, antimony, bismuth, or a combination thereof.

5. The composition of claim 2, wherein A comprises at least one of barium, calcium, beryllium, strontium, magnesium, or a combination thereof.

6. The composition of claim 2, wherein the nanocrystal has a stoichiometry comprising at least one of BaCd₂P₂, CaZn₂P₂, SrCd₂P₂, BaCd₂As₂, CaZn₂As₂, SrCd₂As₂, or a combination thereof.

7. The composition of claim 1, further comprising:
a ligand, wherein:
the ligand is ionically bonded to the nanocrystal.

8. The composition of claim 7, wherein the ligand comprises an organic ligand, an inorganic ligand, or a combination thereof.

9. The composition of claim 8, wherein the organic ligand comprises at least one of oleic acid, sodium oleate, oleylamine, trioctylphosphine, and trioctylphosphine oxide, or a combination thereof.

10. The composition of claim 8, wherein the inorganic ligand is a halide.

11. The composition of claim 1, wherein the bandgap is between 1.4 eV and 1.9 eV.

12. The composition of claim 1, wherein the diameter is between 3 nm to 9 nm.

13. The composition of claim 1, comprising a recombination lifetime of greater than 100 ns to 1000 ns.

14. The composition of claim 1, wherein the nanocrystal has a morphology comprising at least one of a quantum dot, a nanowire, a nanoplate, an amorphous morphology, or a combination thereof.

15. The composition of claim 1, further comprising stability when immersed in liquid water at 25° C.

16. A device comprising:
a layer comprising a nanocrystal, wherein the nanocrystal comprises:
a Zintl-phase;
a P-3m1 space group;
a diameter between 2 nm and 25 nm; and
a bandgap between 0.6 eV and 2.2 eV, wherein:
the layer has a thickness between 3 nm and 3 μm or between 3 nm and 1000 nm or between 3 nm and 500.

17. The device of claim 16, further comprising:
a first charge transport layer (first CTL); and
a second CTL, wherein:
the layer comprising a nanocrystal is positioned between the first CTL and the second CTL.

18. A method comprising:
dissolving a first precursor and a second precursor in a first solution;
adding a third precursor to the first solution to form a second solution; and
mixing the second solution, wherein:
during the mixing, the nanocrystals are formed,
the nanocrystals are characterized by a Zintl-phase having a composition as defined by AM₂X₂,
the first precursor comprises A, the second precursor comprises M, and the third precursor comprises X.

19. The method of claim 18, wherein prior to the adding, removing water from the first solution.

20. The method of claim 18, wherein prior to the adding, heating the first solution to a temperature between 20° C. to 300° C. or between 110° C. to 220° C.
